(19) United States
(12) Patent Application Publication
(10) Pub. No.: US 2012/0121861 A1
(43) Pub. Date: May 17, 2012

(54) SURFACE PATTERNING WITH FUNCTIONAL POLYMERS

(75) Inventors: Werner Hölzl, Eschentzwiller (FR); Holger Braun, Lorrach (DE)

(73) Assignee: BASF SE, Ludwigshafen (DE)

(21) Appl. No.: 13/129,473

(22) PCT Filed: Nov. 5, 2009
(86) PCT No.: PCT/EP2009/064695

§ 371 Date: Oct. 7, 2011

(30) Foreign Application Priority Data
Nov. 14, 2008 (EP) 081690950

(51) Int. Cl. G03F 7/20; B32B 27/00; B32B 3/30

(52) U.S. Cl. 428/156; 430/322

(57) ABSTRACT

Disclosed is a method of preparing a modified halogenated polymer surface, comprising the steps of
(a) activating the surface by modification with a polymerisation initiator by
   (a₁) reacting the halogenated polymer surface with sodium azide, subsequent
   (a₂) patterning the azidated surface via photolithographic patterning methods, and subsequent
   (a₃) 1,3 dipolar cycloaddition with an alkine-functionalized initiator;
and
(b) reacting the activated surface obtained in steps (a₁)-(a₃) with polymerizable monomeric units A and/or B.

In the past decades multitudes of patterning techniques were invented. The driving force behind this development was the microelectronic industries need for obtaining surface patterns with the smallest lateral resolution possible. Miniaturisation opened doors for new applications like biochips for genomic and proteomic analysis, “lab-on-a-chip” systems, organic conductors or tissue engineering.

Currently used patterning methods are:
Photolithography: photolithographic patterns are generated by selectively illuminating a photoactive surface. Irradiation can trigger photopolymerisation, photocrosslinking, functionalisation, decomposition reactions or induce phase separation. The site specific illumination is achieved by using suitable photo masks, lasers computer controlled mirror arrays or applying optical interference methods.

Photolithography is a cost-effective high-throughput technique, which is routinely used by producers of microelectronics or biochips. As a drawback, photolithography can not be applied when working with UV-sensitive materials.
Nanoimprinting: in nanoimprint lithography, a mould is pressed against a soft material, like a thermoplastic or a liquid. The pattern is subsequently trapped either by cooling the thermoplastic (thermal nanoimprint lithography) or by UV curing of the liquid (UV-nano-imprint lithography).
Nanoimprint lithography offers a possibility for the production of highly reproducible patterns.
Microcontact Printing (μCP): microcontact printing is an extremely useful method for the patterning of surfaces with polymer monolayers or thin films. For this technique, a rigid or elastic stamp is used to transfer a material of choice to the substrate. The advantage of this technique is the possibility to produce patterns on large area surfaces with a spatial resolution down to the submicrometer range. Limitations are the difficulty in the production of multilayer and multicomponent patterns.
Dip-pen nanolithography (DPN): dip-pen nanolithography is a method, in which the tip of an AFM cantilever is used to transfer a substrate to a surface via a liquid meniscus between the tip and the surface. With this technique, patterns smaller than 100 nm can be produced.
Ink-jet printing: ink-jet printing is used to deposit solutions of substances onto a surface which form a pattern when the solvent evaporates. Patterning via ink-jet methods has been done in the production of waveguides, microlens arrays, sensors and arrays of cells and proteins. For plastic electronics, e.g. polymer transistor circuits and OLEDs this technique can be seen as the method of choice.
Electron beam lithography: for patterning with electron beam lithography, a substrate is covered with an electron sensitive resist film. The exposed structure is developed (positive or negative) and can be transferred by etching or transfer methods
Focused ion beam lithography: focused ion beams are used to remove atoms from a surface and thus engraving a pattern directly into a surface. By injecting a suitable process gas into the beam, material can as well be deposited onto a surface. The resolution is nearly at the atomic level, which makes focused ion beam lithography a very versatile method.

The present invention relates to a method of preparing patterned polymer structures on halogenated polymer substrates based on a photolithographic method.

It is well known prior art that halogenated polymers like PVC can be modified by wet-chemical methods via nucleophilic substitution of the halogens with small molecule nucleophiles like azides or thiols. Methods of modifying plasticized PVC films by wet-chemical modification methods are disclosed in: J. Sacristán, C. Mijangos, H. Reinecke, Polymer 2000, 41, 5577-5582; J. Reyes-Labarta, M. Herrero, P. Tiemblo, C. Mijangos, H. Reinecke, Polymer 2003, 44, 2263-2269; M. Herrero, R. Navarro, N. García, C. Mijangos, H. Reinecke, Langmuir 2005, 21, 4425-4430.

Surprisingly it has been found, that an azide modified PVC surface can be patterned with photolithographic methods by illuminating the surface through a specific mask with UV light of an appropriate wavelength. The so patterned surface can be further modified by covalently attaching an initiator for free or controlled radical polymerisations like ATRP, RAFT NMP and the like on the surface of the halogenated polymer and subsequent engrafting polymers of defined composition on this modified halogenated polymer surface in a radical polymerization reaction.

The halogenated polymer surface modified in this manner exhibits new properties.

Therefore, the present invention relates to a method of preparing a modified halogenated polymer surface, comprising the steps of
(a) activating the surface by modification with a polymerisation initiator by
   (a₁) reacting the halogenated polymer surface with sodium azide, subsequent
   (a₂) patterning the azidated surface via patterning methods as mentioned above, and subsequent
   (a₃) 1,3 dipolar cycloaddition with an alkine-functionalized initiator;
and
(b) reacting the activated surface obtained in steps (a₁)-(a₃) with polymerizable monomeric units A and/or B.

In the first reaction step (a₁) the halogenated polymer substrate is treated with sodium azide in a manner known per se as for example disclosed by A. Jayakrishnan, M. C. Sunny, Polymer 1996, 37, 5213-5218.

In this reaction step the azide group will be covalently bonded on the surface of the halogenated polymer.

This reaction is preferably carried out in a 1% to 25% aqueous solution of sodium azide at a temperature from 20° C. to 100° C., preferably from 60° C. to 90° C.

The reaction time is from 0.5 h to 2 h, preferably from 1 h to 4 h.

The reaction is preferably carried out in the presence of a phase transfer catalyst, more preferably in the presence of tetrabutyl ammonium bromide.

The activation of the surface can be controlled by IR spectroscopy due to the strong IR activity of the azide.

The degree of modification of the halogenated polymer substrate depends on reaction parameters like reaction time, temperature, solvents and the concentration of the re-agents/reactants.

The reaction (a₁) comprises the steps of interaction of the surface of the polymer substrate with the reaction medium (a₁ₐ), which contemplates the diffusion of the solvent into the upper part of the surface, the second step is the transport of the modification agent to the functional group of the polymer (a_{1b}), and the third step is the reaction itself (a_{1c}).

The reaction step (a₁) can be illustrated by the following reaction scheme:

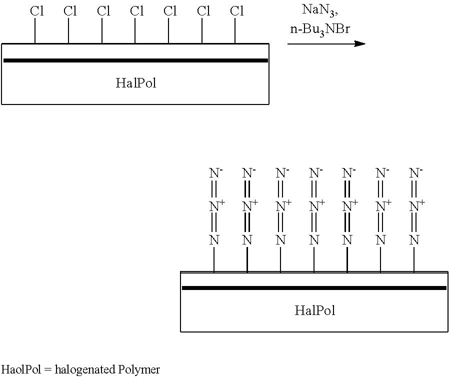

The reaction step (a₂) represents a photochemical decomposition of the azide moiety. It is known, that azide substituted PVC can be degraded with UV light (A. Jaykrishnan, M. C. Sunny, M. N. Rajan, J. Appl. Polym. Sci. 1995, 56, 1187-1195). Under the influence of UV light the azide moiety decompses into a highly active nitrene. This nitrene can undergo several nonselective reactions including cycloaddition to double bonds, insertion into C—H bonds or hydrogen abstraction on the polymer, thereby crosslinking to polymer surface.

The photodecomposition is preferably carried out with a mercury, xenon or deuterium lamp and the sample is illuminated through a suitable photolithographic mask. The azide may be decomposed by light with wavelengthes ranging from 200 nm to 600 nm, preferred is the range from 250 nm to 350 nm.

Preferred is also a radiation with a wavelength of 13 nm in a X-ray diffraction lithography facility. The applied dose range may vary from 20-1600 mJ/cm², applying different types of photomasks.

The reaction time is from 1 min to 3 h, preferably 1 h to 2 h.

Reaction step (a₃) represents a copper-catalyzed 1,3 dipolar cycloaddition with an alkine-functionalized initiator. This reaction is known as Huisgen- or click-reaction.

The reaction step (a₃) can be illustrated by the following reaction scheme:

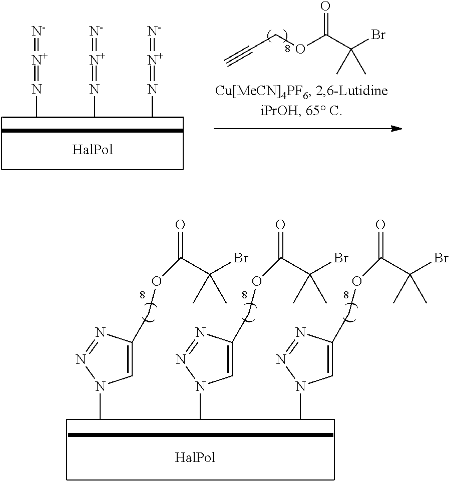

In this reaction step a suitable initiator is bonded to the halogenated polymer substrate.

This reaction is preferably carried out in a 0.1% to 10% solution of the respective alkine in iso-propanol at a temperature from 20° C. to 100° C., preferably at 50° C. to 80° C.

The reaction time is from 0.1 h to 24 h, preferably 10 h to 16 h.

The reaction is preferably carried out in the presence of a copper catalyst and a base, more preferably in the presence of Cu[MeCN]₄PF₆ and 2,6-lutidine.

Examples of halogenated polymers include organic polymers which contain halogenated groups, such as chloropolymers, fluoropolymers and fluorochloropolymers. Examples of halopolymers include fluoroalkyl, difluoroalkyl, trifluoroalkyl, fluoroaryl, difluoroaryl, trifluoroaryl, perfluoroalkyl, perfluoroaryl, chloroalkyl, dichloroalkyl, trichloroalkyl, chloroaryl, dichloroaryl, trichloroaryl, perchloroalkyl, perchloroaryl, chlorofluoroalkyl, chlorofluoroaryl, chlorodifluoro-alkyl, and dichlorofluoroalkyl groups. Halopolymers also include fluorohydrocarbon polymers, such as polyvinylidine fluoride (“PVDF”), polyvinylflouride (“PVF”), polychlorotetrafluoro-ethylene (“PCTFE”), polytetrafluoroethylene (“PTFE”) (including expanded PTFE (“ePTFE”)). Other halopolymers include fluoropolymers perfluorinated resins, such as perfluorinated siloxanes, perfluorinated styrenes, perfluorinated urethanes, and copolymers containing tetra-fluoroethylene and other perfluorinated oxygen-containing polymers like perfluoro-2,2-dimethyl-1,3-dioxide (which is sold under the trade name TEFLON-AF). Still other halopolymers which can be used in the practice of the present invention include perfluoroalkoxy-substituted fluoropolymers, such as MFA (available from Ausimont USA (Thoroughfare, N.J.)) or PFA (available from Dupont (Willmington, Del.)), polytetrafluoroethylene-co-hexafluoropropylene (“FEP”), ethylenechlorotrifluoroethylene copolymer (“ECTFE”), and polyester based polymers, examples of which include polyethyleneterephthalates, polycarbonates, and analogs and copolymers thereof.

Halogen-containing polymers comprise polychloroprene, chlorinated rubbers, chlorinated and brominated copolymer of isobutylene-isoprene (halobutyl rubber), chlorinated or sulfo-chlorinated polyethylene, copolymers of ethylene and chlorinated ethylene, epichlorohydrin homo- and copolymers, especially polymers of halogen-containing vinyl compounds, for example polyvinyl chloride, polyvinylidene chloride, polyvinyl fluoride, polyvinylidene fluoride, as well as copolymers thereof such as vinyl chloride/vinylidene chloride, vinyl chloride/vinyl acetate or vinylidene chloride/vinyl acetate copolymers.

The term “polyvinyl chloride” means compositions whose polymer is a vinyl chloride homopolymer. The homopolymer may be chemically modified, for example by chlorination.

They are in particular polymers obtained by copolymerization of vinyl chloride with monomers containing an ethylenically polymerizable bond, for instance vinyl acetate, vinylidene chloride; maleic or fumaric acid or esters thereof; olefins such as ethylene, propylene or hexene; acrylic or methacrylic esters; styrene; vinyl ethers such as vinyl dodecyl ether.

The compositions according to the invention may also contain mixtures based on chlorinated polymers containing minor quantities of other polymers, such as halogenated polyolefins or acrylonitrile/butadiene/styrene copolymers.

Usually, the copolymers contain at least 50% by weight of vinyl chloride units and preferably at least 80% by weight of such units.

In general, any type of polyvinyl chloride is suitable, irrespective of its method of preparation. Thus, the polymers obtained, for example, by performing bulk, suspension or emulsion processes may be stabilised using the composition according to the invention, irrespective of the intrinsic viscosity of the polymer.

Preferably, the initiator represents the fragment of a polymerization initiator capable of initiating polymerization of ethylenically unsaturated monomers in the presence of a catalyst which activates controlled radical polymerization.

The initiator is preferably selected from the group consisting of C₁-C₈-alkylhalides, C₆-C₁₅-aralkylhalides, C₂-C₈-haloalkyl esters, arene sulphonyl chlorides, haloalkanenitriles, α-haloacrylates and halolactones.

Specific initiators are selected from the group consisting of α,α′-dichloro- or α,α′-dibromoxylene, p-toluenesulfonylchloride (PTS), hexakis-(α-chloro- or α-bromomethyl)-benzene, 1-phenethyl chloride or bromide, methyl or ethyl 2-chloro- or 2-bromopropionate, methyl or ethyl-2-bromo- or 2-chlorooisobutyrate, and the corresponding 2-chloro- or 2-bromopropionic acid, 2-chloro- or 2-bromoisobutyric acid, chloro- or bromoacetonitrile, 2-chloro- or 2-bromo-propionitrile, α-bromo-benzacetonitrile, α-bromo-γ-butyrolactone (=2-bromo-dihydro-2(3H)-furanone) and the initiators derived from 1,1,1-(tris-hydroxymethyl)propane and pentaerythritol of the formulae of above.

The reaction step (b) can be illustrated by the following reaction scheme:

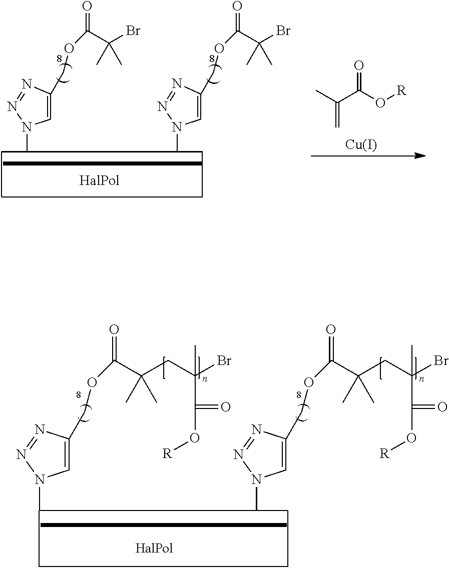

In this reaction a copper catalyzed ATRP reaction with a suitable monomer is performed, which leads to surface bound polymer strands, so called polymer brushes.

This reaction is preferably carried out in a 5% to 50% solution of the respective monomer in a mixture of water and an alcohol or in an alcohol at a temperature from 20° C. to 100° C., preferably at 20° C. to 60° C.

The reaction time is from 0.1 h to 24 h, preferably 1 h to 4 h.

The reaction is preferably carried out in the presence of a catalyst system, more preferably in the presence of CuBr, CuBr₂ and Bipyridin.

### Monomers

The monomers useful in the present polymerization processes can be any radically (co)polymerizable monomer. Within the context of the present invention, the phrase “radically (co)-polymerizable monomer” indicates that the monomer can be either homopolymerized by radical polymerization or can be radically copolymerized with another monomer, even though the monomer in question cannot itself be radically homopolymerized. Such monomers typically include any ethylenically unsaturated monomer, including but not limiting to styrenes, acrylates, methacrylates, acrylamides, acrylonitriles, isobutylene, dienes, vinyl acetate, N-cyclohexyl maleimide, 2-hydroxyethyl acrylates, 2-hydroxyethyl methacrylates, and fluoro-containing vinyl monomers. These monomers can optionally be substituted by any substituent that does not interfere with the polymerization process, such as alkyl, alkoxy, aryl, heteroaryl, benzyl, vinyl, allyl, hydroxy, epoxy, amide, ethers, esters, ketones, maleimides, succinimides, sulfoxides, glycidyl or silyl.

The polymers may be prepared from a variety of monomers. A particularly useful class of water-soluble or water-dispersible monomers features acrylamide monomers corresponding to the formula

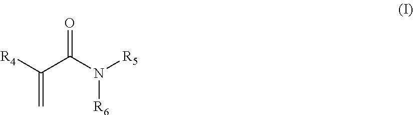

wherein
R₄ is H or an alkyl group; and
R₅ and R₆, independently, are selected from the group consisting of hydrogen, alkyl, substituted alkyl, cycloalkyl, substituted cycloalkyl, heteroalkyl, heterocycloalkyl, substituted heterocycloalkyl, aryl, substituted aryl, heteroaryl, substituted heteroaryl, alkoxy, aryloxy, and combinations thereof; R₅ and R₆ may be joined together in a cyclic ring structure, including heterocyclic ring structure, and that may have fused with it another saturated or aromatic ring. An especially preferred embodiment is where R₅ and R₆, independently, are selected from the group consisting of hydroxy-substituted alkyl, polyhydroxy-substituted alkyl, amino-substituted alkyl, polyamino-substituted alkyl and isothiocyanato-substituted alkyl. In preferred embodiments, the polymers include the acrylamide-based repeat units derived from monomers such as acrylamide, methacrylamides, N-alkylacrylamide (e.g., N-methylacrylamide, N-tert-butylacrylamide, and N-n-butylacryl-amide), N-alkylmethacrylamide (e.g., N-tert-butylmethacrylamide and N-n-butyl-methacrylamide), N,N-dialkylacrylamide (e.g., N,N-dimethylacrylamide), N-methyl-N-(2-hydroxyethyl)acrylamide, N,N-dialkylmethacrylamide, N-methylolmethacrylamide, N-ethylolmethacrylamide, N-methylolacrylamide, N-ethylolacrylamide, and combinations thereof. In another preferred embodiment, the polymers include acrylamidic repeat units derived from monomers selected from N-alkylacrylamide, N-alkylmethacrylamide, N,N-dialkylacrylamide and N,N-dialkylmethacrylamide. Preferred repeat units can be derived, specifically, from acrylamide, methacrylamide, N,N-dimethylacrylamide, and tert-butylacrylamide.

Copolymers can include two or more of the aforementioned acrylamide-based repeat units. Copolymers can also include, for example, one or more of the aforementioned polyacryl-amide-based repeat units in combination with one or more other repeat units.

Generally speaking, in some embodiments of the present invention the monomer may be represented by the following formula

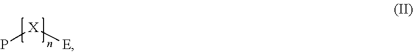

wherein
P is a functional group that polymerizes in the presence of free radicals (e.g., carbon-carbon double bond), and
E is a group that can react with the probe of interest and form a chemical bond therewith. The bond which forms between E, or a portion thereof, and the probe in most cases is covalent, or has a covalent character. It is to be noted, however, that the present invention also encompasses other type of bonds or bonding (e.g., hydrogen bonding, ionic bonding, metal coordination, or combinations thereof).

One example of the latter is when the E group contains a metal complexing agent that can bind a protein through a mixed complex: E can be, for instance, a ligand, such as iminodiacetic acid that can bind histidine tagged proteins through Ni mixed complexes.

E can be for example, but is not limited to, isothiocyanates, isocyanates, acylacycles, aldehydes, amines, sulfonylchlorides, epoxides, carbonates, acidifluorides, acidchlorides, acid-bromides, acidanhydrides, acylimidazoles, thiols, alkyl halides, maleimides, aziridines and oxiranes.

In another embodiment, E is a phenylboronic acid moiety, which can strongly complex to biological probes that contains certain polyol molecules (e.g., 1,2-cis diols or other related compounds). In one preferred embodiment, E is an electrophilic group that, upon reaction with a nucleophilic site present in the probe, forms a chemical bond with the probe. Such activated monomers include, but are not limited to, N-hydroxysuccinimides, tosylates, brosylater, nosylates, mesylates, etc. In other embodiments, the electrophilic group consists of a 3- to 5-membered ring which opens upon reaction with the nucleophile. Such cyclic electrophiles include, but are not limited to, epoxides, oxetanes, aziridines, azetidines, episulfides, 2-oxazolin-5-ones, etc. In still other embodiments, the electrophilic group may be a group wherein, upon reaction with the nucleophilic probe, an addition reaction takes place, leading to the formation of a covalent bond between the probe and the polymer. These electrophilic groups include, but are not limited to, maleimide derivatives, acetylacetoxy derivatives, etc.

With respect to X, it is to be noted that, when present (i.e., when nm is not equal to zero), X represents some linking group which connects P to E, such as in the case of X linking an unsaturated carbon atom of P to an electrophilic E group. X may be, for example, a substituted or unsubstituted hydrocarbylene or heterohydrocarbylene linker, a hetero linker, etc., including linkers derived from alkyl, amino, aminoalkyl or aminoalkylamido groups. In such instances, m is an integer such as 1, 2, 3, 4 or more. In other embodiments (i.e., when m is equal to zero), P is directly bound to E.

In one preferred embodiment, X is a linker generally represented by the formula

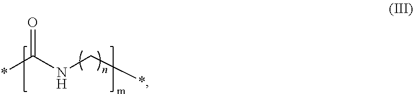

wherein
n is an integer from about 1 to about 5, and
m is an integer from about 1 to about 2, 3, 4 or more. In one such embodiment.

Preferred monomers include those having an N-hydroxysuccinimide group.

For example, certain of such monomers may generally be represented by the following formula

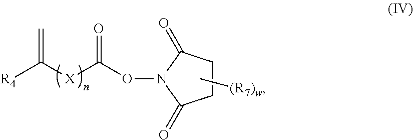

wherein
R₄ is a hydrogen or an alkyl substitutent, and R₇ is one or more substituents (i.e., w is 1, 2, 3, 4) selected from the group consisting of hydrogen substituted or unsubstituted hydrocarbyl (e.g., alkyl, aryl, heteroalkyl), heterohydrocarbyl, alkoxy, substituted or unsubstituted aryl, sulphates, thioethers, ethers, hydroxy, etc. Generally speaking, R₇ can essentially any substituent that does not substantially decrease the hydrophilic of the water-soluble or water-dispersible segment in which it is contained. In this regard it is to be noted that a number of substituted succinimide compounds are commercially available and are suitable for use in the present invention.

Among the particularly preferred monomers is included N-acryloxysuccinimide and 2-(meth-acryloyloxy)ethylamino N-succinimidyl carbamate, which are generally represented by the formulas

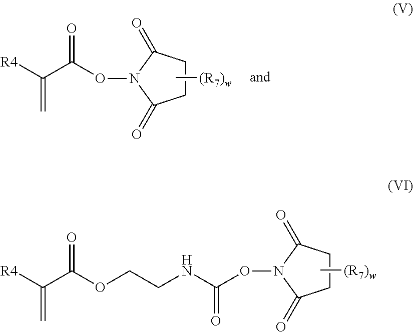

wherein
R₄, R₇ and w are defined as in formula (IV).

Also preferred are those monomers represented by formulas

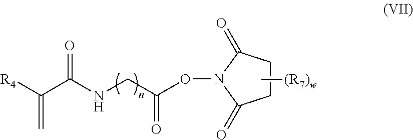

and (VII) below, wherein the terminal carbonyl-oxo-succinimide group is positioned further from the polymer chain backbone by the oresence of a aminoalkyl or aminoalkylamido linker (i.e., “X”), respectively

### (VII) and

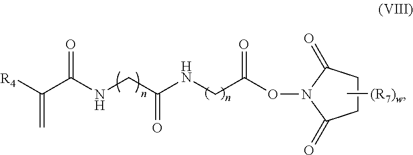

wherein
R₄, R₇, n and w are defined as in formula (IV).

Alternatively, however, monomers such as 2-(methylacryloyloxy)ethyl acetoacetate, glycidyl methacrylate (GMA) and 4,4-dimethyl-2-vinyl-2-oxazolin-5-one, generally represented by formulas

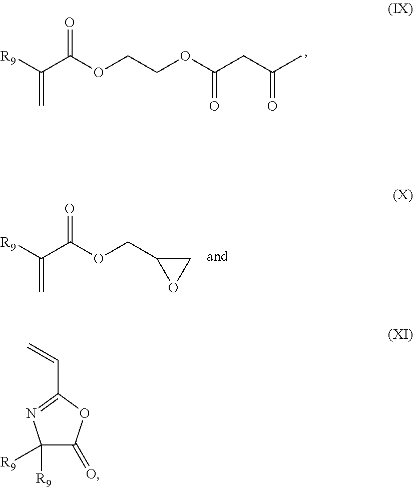

respectively, may also be employed (wherein R₉ is hydrogen or hydrocarbyl, such as methyl, ethyl, propyl, etc., as defined herein).

One or more of the above referenced monomers (e.g., N-acryloxysuccinimide, 2-(methyl-acryloyloxy)ethyl acetoacetate, glycidyl methacrylate and 4,4-dimethyl-2-vinyl-2-oxazolin-5-one) are commercially available, for example from Aldrich Chemical Company. Additionally, monomers generally represented by formulas (VII) and (VIII), above, may be prepared by means common in the art.

It is to be noted that such monomers may advantageously be employed in any of the polymerization processes described herein, including nitroxide and iniferter initiated systems.

Suitable polymerization monomers and comonomers of the present invention include, but are not limited to, methyl methacrylate, ethyl acrylate, propyl methacrylate (all isomers), butyl methacrylate (all isomers), 2-ethylhexyl methacrylate, isobornyl methacrylate, methacrylic acid, benzyl methacrylate, phenyl methacrylate, methacrylonitrile, alpha-methylstyrene, methyl acrylate, ethyl acrylate, propyl acrylate (all isomers), butyl acrylate (all isomers), 2-ethyl-hexyl acrylate, isobornyl acrylate, acrylic acid, benzyl acrylate, phenyl acrylate, acrylonitrile, styrene, acrylates and styrenes selected from glycidyl methacrylate, 2-hydroxyethyl meth-acrylate, hydroxypropyl methacrylate (all isomers), hydroxybutyl methacrylate (all isomers), N,N-dimethylaminoethyl methacrylate, N,N-diethylaminoethyl methacrylate, triethyleneglycol methacrylate, itaconic anhydride, itaconic acid, glycidyl acrylate, 2-hydroxyethyl acrylate, hydroxypropyl acrylate (all isomers), hydroxybutyl acrylate (all isomers), N,N-dimethylamino-ethyl acrylate, N,N-diethylaminoacrylate, triethyleneglycol acrylate, methacrylamide, N-methylacrylamide, N,N-dimethylacrylamide, N-tert-butylmethacrylamide, N-n-butylmeth-acrylamide, N-methylolacrylamide, N-ethylolacrylamide, vinyl benzoic acid (all isomers), di-ethylaminostyrene (all isomers), alpha-methylvinyl benzoic acid (all isomers), diethylamino alpha-methylstyrene (all isomers), p-vinylbenzenesulfonic acid, p-vinylbenzene sulfonic sodium salt, trimethoxysilylpropyl methacrylate, triethoxysiiylpropyl methacrylate, tributoxy-silylpropyl methacrylate, dimethoxymethylsilylpropyl methacrylate, diethoxymethylsilylpropyl methacrylate, dibutoxymethylsilylpropyl methacrylate, diisopropyoxymethylsilylpropyl meth-acrylate, dimethoxysilylpropyl methacrylate, diethoxysilylpropyl methacrylate, dibutoxysilyl-propyl methacrylate, diisopropoxysilylpropyl methacrylate, trimethoxysilylpropyl acrylate, triethoxysilylpropyl acrylate, tributoxysilylpropyl acrylate, dimethoxymethylsilylpropyl acrylate, diethoxymethylsilylpropyl acrylate, dibutoxymethylsilylpropyl acrylate, diisopropoxymethylsilylpropyl acrylate, dimethoxysilylpropyl acrylate, diethoxysilylpropyl acrylate, dibutoxysilyl-propyl acrylate, diisopropoxysilylpropyl acrylate, vinyl acetate, vinyl butyrate, vinyl benzoate, vinyl chloride, vinyl flouride, vinyl bromide, maleic anhydride, N-phenyl maleimide, N-butyl-maleimide, N-vinylpyrrolidone, N-vinylcarbazole, betaines, sulfobetaines, carboxybetaines, phosphobetaines, butadiene, isoprene, chloroprene, ethylene, propylene, 1,5-hexadienes, 1,4-hexadienes, 1,3-butadienes, and 1,4-pentadienes.

Additional suitable polymerizable monomers and comonomers include, but are not limited to, vinyl acetate, vinyl alcohol, vinylamine, N-alkylvinylamine, allylamine, N-alkylallylamine, di-allylamine, N-alkyldiallylamine, alkylenimine, acrylic acids, alkylacrylates, acrylamides, meth-acrlic acids, maleic anhydride, alkylmethacrylates, n-vinyl formamide, vinyl ethers, vinyl naphthalene, vinyl pyridine, vinyl sulfonates, ethylvinylbenzene, aminostyrene, vinylbiphenyl, vinylanisole, vinylimidazolyl, vinylpyridinyl, dimethylaminomethystyrene, trimethylammonium ethyl methacrylate, trimethylammonium ethyl acrylate, dimethylamino propylacrylamide, tri-methylammonium ethylacrylate, trimethylammonium ethyl methacrylate, trimethylammonium propyl acrylamide, dodecyl acrylate, octadecyl acrylate, and octadecyl methacrylate.

“Betaine”, as used herein, refers to a general class of salt compounds, especially zwitterionic compounds, and include polybetaines. Representative examples of betaines which can be used with the present invention include: N,N-dimethyl-N-acryloyloxyethyl-N-(3-sulfopropyl)-ammonium betaine, N,N-dimethyl-N-acrylamidopropyl-N-(2-carboxymethyl)-ammonium betaine, N,N-dimethyl-N-acrylamidopropyl-N-(3-sulfopropyl)-ammonium betaine, N,N-dimethyl-N-acrylamidopropyl-N-(2-carboxymethyl)-ammonium betaine, 2-(methylthio)ethyl methacryloyl-S-(sulfopropyl)-sulfonium betaine, 2-[(2-acryloylethyl)dimethylammonio]ethyl 2-methyl phosphate, 2-(acryloyloxyethyl)-2′-(trimethylammonium)ethyl phosphate, [(2-acryloylethyl)-dimethylammonio)methyl phosphonic acid, 2-methacryloyloxyethyl phosphorylcholine (MPC), 2-[(3-acrylamidopropyl)dimethylammonio]ethyl 2′-isopropyl phosphate (AAPI), 1-vinyl-3-(3-sulfopropyl)imidazolium hydroxide, (2-acryloxyethyl)carboxymethyl methylsulfonium chloride, 1-(3-sulfopropyl)-2-vinylpyridinium betaine, N-(4-sulfobutyl)-N-methyl-N,N-diallylamine ammonium betaine (MDABS), N,N-diallyl-N-methyl-N-(2-sulfoethyl)ammonium betaine, and the like.

It is to be understood, that the above described functional monomers, especially monomers containing basic amino groups, can also be used in form of their corresponding salts. For example acrylates, methacrylates or styrenes containing amino groups can be used as salts with organic or inorganic acids or by way of quaternisation with known alkylation agents like benzyl chloride. The salt formation can also be done as a subsequent reaction on the preformed block copolymer with appropriate reagents. In another embodiment, the salt formation is carried out in situ in compositions or formulations, for example by reacting a block copolymer with basic or acidic groups with appropriate neutralisation agents during the preparation of a pigment concentrate.

The grafted polymers formed on the surface of the halogenated polymer substrate form thin layers of 5 nm to 100 μm, preferably 10 nm to 200 nm and distinguish by a low polydisperisty which is <3.

The layer thickness of the polymers formed on the surface is dependent on the parameters like solvents, concentration of reactands, temperature and/or reaction time.

If necessary, these polymers may be present in form of polymer brushes, i.e. in form of chains which are oriented perpendicular to the surface.

“Polymer brushes,” as the name suggests, contain polymer chains, one end of which is directly or indirectly tethered to a surface and another end of which is free to extend from the surface, somewhat analogous to the bristles of a brush.

Covalent attachment of polymers to form polymer brushes is commonly achieved by “grafting to” and “grafting from” techniques. “Grafting to” techniques involve tethering pre-formed end-functionalized polymer chains to a suitable substrate under appropriate conditions. “Grafting from” techniques, on the other hand, involve covalently immobilizing initiators on the substrate surface, followed by surface initiated polymerization to generate the polymer brushes.

Each of these techniques involves the attachment of a species (e.g., a polymer or an initiator) to a surface, which may be carried out using a number of techniques that are known in the art.

As noted above, in the “grafting from” process once an initiator is attached to the surface, a polymerization reaction is then conducted to create a surface bound polymer. Various polymerization reactions may be employed, including various condensations, anionic, cationic and radical polymerization methods. These and other methods may be used to polymerize a host of monomers and monomer combinations.

Specific examples of radical polymerization processes are controlled/“living” radical polymerizations such as metal-catalyzed atom transfer radical polymerization (ATRP), stable free-radical polymerization (SFRP), nitroxide-mediated processes (NMP), and degenerative transfer (e.g., reversible addition-fragmentation chain transfer (RAFT)) processes, among others. The advantages of using a “living” free radical system for polymer brush creation include control over the brush thickness via control of molecular weight and narrow polydispersities, and the ability to prepare block copolymers by the sequential activation of a dormant chain end in the presence of different monomers. These methods are well-detailed in the literature and are described, for example, in an article by Pyun and Matyjaszewski, “Synthesis of Nanocomposite Organic/Inorganic Hybrid Materials Using Controlled/“Living” Radical Polymerization,” Chem. Mater., 13:3436-3448 (2001), the contents of which are incorporated by reference in its entirety.

If necessary, the first polymerization may be interrupted and a further polymerisation may be started with a new monomer in order to form block polymers.

The term polymer comprises oligomers, cooligomers, polymers or copolymers, such as block, multi-block, star, gradient, random, comb, hyperbranched and dendritic copolymers as well as graft copolymers. The block copolymer unit A contains at least two repeating units (x≧2) of polymerizable aliphatic monomers having one or more olefinic double bonds. The block copolymer unit B contains at least one polymerizable aliphatic monomer unit (y≧0) having one or more olefinic double bonds.

The modified halogenated polymer substrate prepared according to the process of the present invention represents a further embodiment of the present invention.

The modified halogenated polymer can be illustrated by the following formula

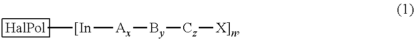

wherein

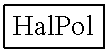

represents the halogenated polymer substrate;
In represents the fragment of a polymerisation initiator capable of initiating polymerisation of ethylenically unsaturated monomers in the presence of a catalyst which activates controlled radical polymerisation;
A represents an oligopolymer or polymer fragment (polymer brush) ???formed from ethylenically unsaturated repeating units of polymerizable monomers or oligopolymers;
x represents a numeral greater than one and defines the number of repeating units in A;
B represents a monomer, oligopolymer or polymer fragment (polymer brush) formed from ethylenically unsaturated repeating units of polymerizable monomers or oligopolymers copolymerized with A;
y represents zero or a numeral greater than zero and defines the number of monomer, oligopolymer or polymer repeating units in B;
C represents a monomer, oligopolymer or polymer fragment (polymer brush) formed from ethylenically unsaturated repeating units of polymerizable monomers or oligopolymers copolymerized with A and/or B;
z represents zero or a numeral greater than zero and defines the number of monomer, oligopolymer or polymer repeating units in C;
n is one or a numeral greater than one which defines the number of groups of the partial formula (1a) In-(Aₓ-B_{y}-C_{z}-X).

The subunits A, B, and C can be further subdivided into the general formula

P-[X]ₘ-E, (1b)

wherein
P is a functional group that polymerizes in the presence of free radicals, e.g. an unsaturated carbon-carbon bond. X, when present (i.e. when m ist not equal to zero), represents some kind of linking group, which connects P to E, such as in the case of X linking an unsaturated carbon atom of P to E.
X may be, for example, a substituted or unsubstituted hydrocarbylene or heterohydro-carbylene linker, a hetero linker etc. including but not limiting linkers derived from alkyl, amino, aminoalkyl or aminoalkylamido groups. In such instances, m is an integer such as 1, 2, 3, 4 or more. In other embodiments (i.e. when m is equal to zero), P is directly bound to E.

E is a group, which can react with a probe of interest and form a chemical bond therewith. The bond which forms between E, or a portion thereof, and a probe of interest encompasses covalent bonding, ionic bonding, hydrogen bonding, metal coordination, π-π interactions, π-stacking, van der Waals interactions, cation-π interactions and combinations thereof.

In the context of the description of the present invention, the term alkyl comprises methyl, ethyl and the isomers of propyl, butyl, pentyl, hexyl, heptyl, octyl, nonyl, decyl, undecyl and dodecyl. An example of aryl-substituted alkyl is benzyl. Examples of alkoxy are methoxy, ethoxy and the isomers of propoxy and butoxy. Examples of alkenyl are vinyl and allyl. An example of alkylene is ethylene, n-propylene, 1,2- or 1,3-propylene.

Some examples of cycloalkyl are cyclopropyl, cyclobutyl, cyclopentyl, cyclohexyl, methylcyclopentyl, dimethylcyclopentyl and methylcyclohexyl. Examples of substituted cycloalkyl are methyl-, dimethyl-, trimethyl-, methoxy-, dimethoxy-, trimethoxy-, trifluoromethyl-, bis-trifluoromethyl- and tris-trifluoromethyl-substituted cyclopentyl and cyclohexyl.

Examples of aryl are phenyl and naphthyl. Examples of aryloxy are phenoxy and naphthyloxy. Examples of substituted aryl are methyl-, dimethyl-, trimethyl-, methoxy-, dimethoxy-, trimethoxy-, trifluoromethyl-, bis-trifluoromethyl- or tris-trifluoromethyl-substituted phenyl. An example of aralkyl is benzyl. Examples of substituted aralkyl are methyl-, dimethyl-, trimethyl-, methoxy-, dimethoxy-, trimethoxy-, trifluoromethyl-, bis-trifluoromethyl or tris-trifluoro-methyl-substituted benzyl.

Some examples of an aliphatic carboxylic acid are acetic, propionic or butyric acid. An example of a cycloaliphatic carboxylic acid is cyclohexanoic acid. An example of an aromatic carboxylic acid is benzoic acid. An example of a phosphorus-containing acid is methylphosphonic acid. An example of an aliphatic dicarboxylic acid is malonyl, maleoyl or succinyl. An example of an aromatic dicarboxylic acid is phthaloyl.

The term heterocycloalkyl embraces within the given structure one or two and heterocyclic groups having one to four heteroatoms selected from the group consisting of nitrogen, sulphur and oxygen. Some examples of heterocycloalkyl are tetrahydrofuryl, pyrrolidinyl, piperazinyl and tetrahydrothienyl. Some examples of heteroaryl are furyl, thienyl, pyrrolyl, pyridyl and pyrimidinyl.

An example of a monovalent silyl radical is trimethylsilyl.

The process can be used to generate polymer patterns of any 2-dimensional structure on the surface by applying the above described method for grafting polymer brushes from non-decomposed areas.

The modified halogenated polymer substrate according to the present invention can be used:
to construct devices, which exploit the heterogenous physical properties of the surface, which may be for instance devices for identifying components of complex mixtures, for controlling cellular adhesion on the surface or for controlling mixing and flow of liquids.
to generate structured metallic thin films on the surface by chemical plating, as it is described for other substrates and patterning techniques elsewhere. Polyelectrolyte brushes are grafted onto the patterned surface as described above in order to establish the anchoring layer for the catalytic species of the process and the subsequent metallic film. The adhesion of the latter is very strong, as can be shown by a simple qualitative peel-off test with a scotch tape.
B-group elements, which can be reduced from aqueous solution might be deposited onto the surface, preferred are Ni, Cu, Ag, Au. Polyelectrolyte brushes might be polycationic or polyanionic, depending on the charge of the catalytic species. Preferred in this embodiment are polycationic brushes as accordingly substituted ammonium acrylates together with a negatively charged catalytically active Pd-compound as salts from tetra-chloropalladium(II) acid.

The following examples demonstrate the process, which is not limited to conditions as described:

By grafting zwitterionic acrylates onto patterned surfaces hydrophilicly/hydrophobicly structured areas are generated, which exhibit distinctly different properties as for instance wettability compared to non-modified or homogenously modified surfaces.

### EXAMPLE 1

Solid PVC substrate (film) is reacted in 250 ml of a 5% aqueous NaN₃ solution and n-tetrabutylammonium bromide (c=40 mmol/l) at 80° C. for 4 h.

For purification the film is treated with water in an ultrasonic bath.

IR spectra clearly show an azidation of the surface.

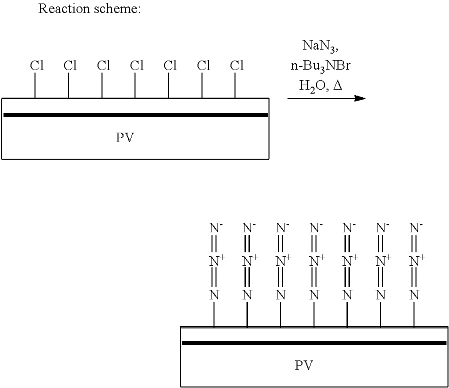

After activation of the PVC substrate a suitable initiator can be covalently bonded at the surface via a copper-catalysed 1,3-dipolar addition.

### EXAMPLE 2

The azidated PVC Film is illuminated for 1.5 h through a photomask with a Lot ORIEL mercury lamp.

The azidated PVC-foil is subjected to radiation with a wavelength of 13 nm in a X-ray diffraction lithography facility. The applied dose range may vary from 20-1600 mJ/cm², applying different types of photomasks.

### EXAMPLE 3

The PVC film as prepared in Example 2 together with 1.8 g of the alkin-initiator and 1.8 g of 2,6-lutidine is added to 210 ml of iso-propanol, heated up to 65° C. and degassed by bubbling nitrogen through the solution for 30 min.

Then Cu[MeCN]₄PF₆ (70 mg) is added and the reaction mixture stirred over night at 65° C. The obtained film is washed with deionised water and methanol

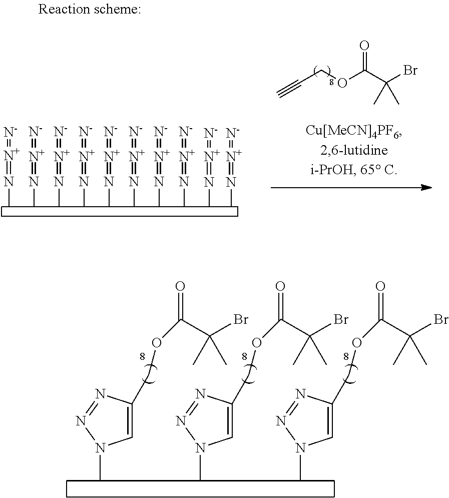

### EXAMPLE 4

33.4 g (119.7 mmol) of a monomer unit is exhibited in a mixture of methanol and water.

After addition of 933.8 mg (5.978 mmol) bipiridyl and 53 mg (0.238 mmol) copper(II)bromide the solution is degassed with nitrogen.

343 mg (2.394 mmol) copper(I)bromide and the activated film are added to the degassed solution. The reaction mixture is agitated for 1 h at room temperature.

For completion of the reaction the film is removed from the reaction mixture, washed in an ultrasonic bath and dried.

The film shows a mass increase of 6.3 mg.

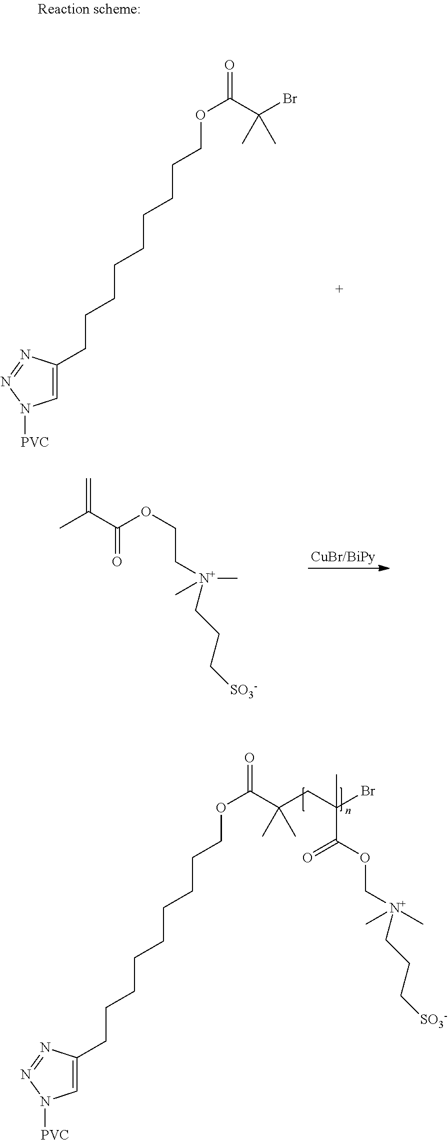

The elemental composition of the PVC sample surface is measured with ESCA technique. The size of the analyzed area is 100 micrometers in diameters. The depth of the analysis is 5 nanometers.

The results in the table below are averages of the two measurements.

Surface elemental composition (atomic %) of the PVC sample

| Sample | C | O | N | S |
|---|---|---|---|---|
| PVC | 66.4 | 25.3 | 4.5 | 4.0 |

The surface pattern was determined with an atomic force microscope

### EXAMPLES 5 AND 6

### Deposition of a Thin Metalic Film

### EXAMPLE 5

### Grafting of the Polyelectrolyte Layer onto the Surface

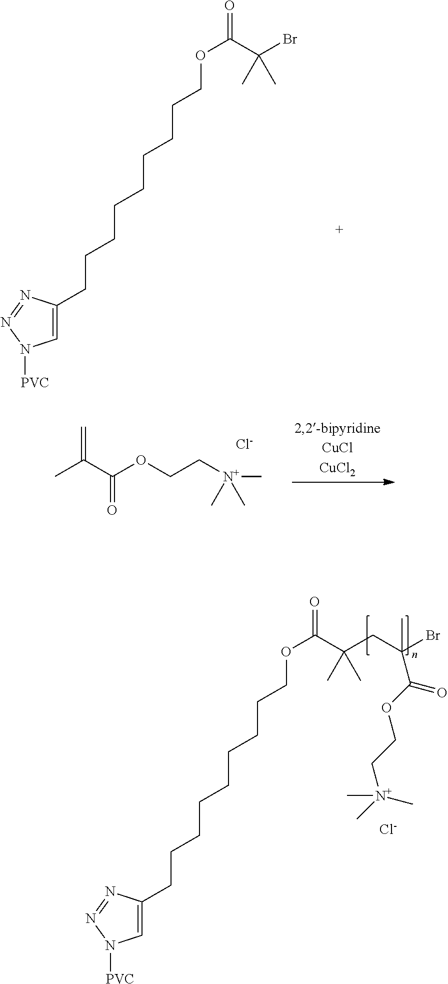

23.15 g 2-(methacryloyloxy)ethyl-trimethylammonium chloride (75% ig in water) are dissolved in 23 ml methanol. nitrogen is passed through the solution for 30 min with stirring and 1.26 g 2,2′-bipyridine, 0.306 g CuCl and 0.042 g CuCl₂ are added. After additional 15 min of degassing the patterned, initiator-modified PVC-foil is put into the solution and treated for 6 h with stirring at room temperature.

The foil is removed from the reaction solution and intensively washed with water and methanol and dried under a stream of nitrogen.

### EXAMPLE 6

### Chemical Plating of Copper

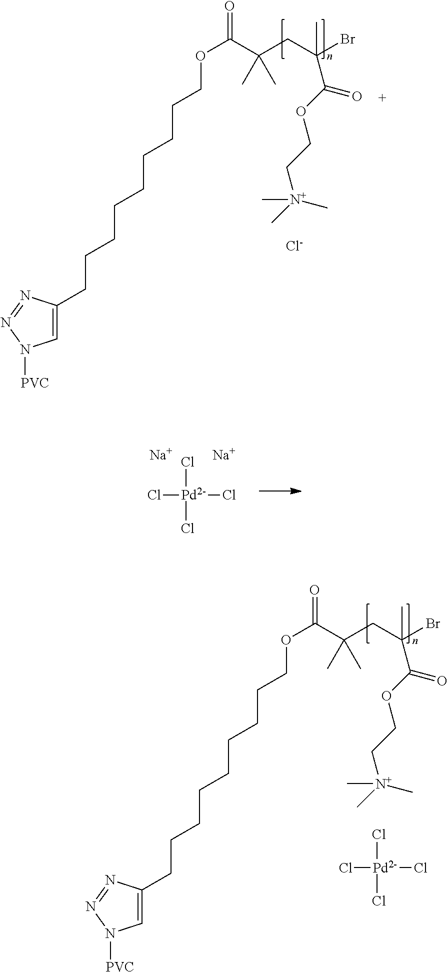

The foil treated as described above is dipped into a 1 mM solution of Na₂PdCl₄ in water for 20 min at room temperature and is then washed intensively with water.

For the plating process two solutions are prepared:

### Solution A:

NaOH 12 g/l
CuSO₄*5H₂O 13 g/l
KNaC₄H₄O₆*4H₂O (potassium sodium tartrate)

### Solution B:

formaldehyde (36% in water) 9.5 ml/l

For plating equal amounts of each solution (freshly prepared) are mixed and the foil is put into this mixture under stirring at room temperature for 5 min. A homogenous film of metallic copper forms immediately according to the applied pattern.

1-10. (canceled)

11. A method of preparing a modified halogenated polymer surface, comprising the steps of
(a) activating the surface by modification with a polymerisation initiator by
(a₁) reacting the halogenated polymer surface with sodium azide, subsequent
(a₂) patterning the azidated surface via photolithographic patterning methods, and subsequent
(a₃) 1,3 dipolar cycloaddition with an alkine-functionalized initiator;
and
(b) reacting the activated surface obtained in steps (a₁)-(a₃) with polymerizable monomeric units A and/or B.

12. The method according to claim 11, wherein the initiator represents the fragment of a polymerization initiator capable of initiating polymerization of ethylenically unsaturated monomers in the presence of a catalyst which activates controlled radical polymerization.

13. The method according to claim 11, wherein the initiator is selected from the group consisting of C₁-C₈-alkylhalides, C₆-C₁₅-aralkylhalides, C₂-C₈-haloalkyl esters, arene sulphonyl chlorides, haloalkanenitriles, α-haloacrylates and halolactones.

14. The method according to claim 11, wherein the polymerizable monomeric units A and B are copolymerized by atom transfer radical polymerization (ATRP) participating the initiator of the activated surface obtained in steps (a₁)/(a₂) or (a₃).

15. The method according to claim 11, wherein the polymerizable monomeric units A and B differ in polarity and contain one or more olefinic double bond.

16. The method according to claim 11, wherein the polymerizable monomeric units A and B are selected from styrenes, acrylic acid, C₁-C₄-alkylacrylic acid, amides, anhydrides and salts of acrylic acid or C₁-C₄-alkylacrylic acid, acrylic acid-C₁-C₂₄-alkyl esters and C₁-C₄-alkylacrylic acid-C₁-C₂₄-alkyl esters.

17. The method according to claim 11, wherein the polymerizable monomeric units A and B are selected from the group consisting of 4-aminostyrene, di-C₁-C₄-alkylaminostyrene, styrene, acrylic acid, C₁-C₄-alkylacrylic acid, acrylic or C₁-C₄-alkylacrylamides, acrylic or C₁-C₄-alkylacrylmono- or -di-C₁-C₄-alkylamides, acrylic or C₁-C₄-alkylacryl-di-C₁-C₄-alkyl-amino-C₂-C₄-alkylamides, acrylic or C₁-C₄-alkylacryl-amino-C₂-C₄alkylamides, anhydrides and salts of acrylic acid or C₁-C₄-alkylacrylic acid, acrylic or C₁-C₄-alkylacrylic acid-mono- or -di-C₁-C₄-alkylamino-C₂-C₄-alkyl esters, acrylic or C₁-C₄-alkylacrylic acid-hydroxy-C₂-C₄-alkyl esters, acrylic or C₁-C₄-alkylacrylic acid-(C₁-C₄-alkyl)₃silyloxy-C₂-C₄-alkyl esters, acrylic or C₁-C₄-alkylacrylic acid-(C₁-C₄-alkyl)₃silyl-C₂-C₄-alkyl esters, acrylic or C₁-C₄-alkylacrylic acid-heterocyclyl-C₂-C₄-alkyl esters, C₁-C₂₄-alkoxylated poly-C₂-C₄-alkylene glycol acrylic or C₁-C₄-alkylacrylic acid esters, acrylic acid-C₁-C₂₄-alkyl esters and C₁-C₄-alkylacrylic acid-C₁-C₂₄-alkyl esters.

18. A modified halogenated polymer surface obtained in a method comprising:
(a) activating the surface by modification with a polymerisation initiator by
(a₁) reacting the halogenated polymer surface with sodium azide, subsequent
(a₂) patterning the azidated surface via photolithographic patterning methods, and subsequent
(a₃) 1,3 dipolar cycloaddition with an alkine-functionalized initiator;
and
(b) reacting the activated surface obtained in steps (a₁)-(a₃) with polymerizable monomeric units A and/or B.

19. The modified halogenated polymer surface according to claim 18, wherein the modified halogenated polymer surface corresponds to the formula
HalPol-[In-Aₓ-B_{y}-C_{z}-X]ₙ, (1)
wherein
A, B, C represent monomer-oligomer or polymer fragments, which can be arranged in block or statstically;
X is halogen which is positioned at the end of each polymer brush as end group derived from ATRP;
HalPol represents the halogenated polymer substrate;
In represents the fragment of a polymerisation initiator capable of initiating polymerisation of ethylenically unsaturated monomers in the presence of a catalyst which activates controlled radical polymerisation;
x represents a numeral greater than one and defines the number of repeating units in A;
y represents zero or a numeral greater than zero and defines the number of monomer, oligopolymer or polymer repeating units in B;
z represents zero or a numeral greater than zero and defines the number of monomer, oligopolymer or polymer repeating units in C;
n is one or a numeral greater than one which defines the number of groups of the partial formula (1a) In-(Aₓ-B_{y}-C_{z}-X)—.

20. A sensor device comprising the modified halogenated polymer surface according to claim 19.
